(19) United States
(12) Patent Application Publication
(10) Pub. No.: US 2026/0029719 A1
(43) Pub. Date: Jan. 29, 2026

(54) SUBSTRATE PROCESSING APPARATUS AND SUBSTRATE PROCESSING METHOD

(71) Applicant: SEMES CO., LTD., Cheonan-si (KR)

(72) Inventors: Gu Won SEON, Seoul (KR); Jae Seung YU, Seoul (KR); Dae Sung KIM, Cheonan-si (KR); Gyeong Won SONG, Cheonan-si (KR)

(73) Assignee: SEMES CO., LTD., Cheonan-si (KR)

(21) Appl. No.: 19/273,633

(22) Filed: Jul. 18, 2025

(30) Foreign Application Priority Data
Jul. 24, 2024 (KR) 10-2024-0097910

(51) Int. Cl. G03F 7/16; B08B 9/032

(52) U.S. Cl. CPC G03F 7/16; B08B 9/0325; B08B 2209/032

(57) ABSTRACT

The apparatus includes a processing unit for processing a substrate; and a liquid supply unit for supplying a liquid to a substrate disposed in the processing unit, in which the liquid supply unit includes: a bottle in which a storage space for storing a liquid is formed; a supply pipe for providing a path through which the liquid in the bottle flows to the processing unit; a trap tank installed in the supply pipe and having an interior space in which the liquid delivered from the bottle is stored; a pump installed in the supply pipe downstream of the trap tank and providing flow pressure to the fluid flowing in the supply pipe; and a negative pressure forming unit for forming negative pressure in the interior space of the trap tank and delivering the liquid in the storage space of the bottle to the trap tank.

### CROSS-REFERENCE TO RELATED APPLICATIONS

This application claims priority to and the benefit of Korean Patent Application No. 10-2024-0097910 filed in the Korean Intellectual Property Office on Jul. 24, 2024, the entire contents of which are incorporated herein by reference.

### TECHNICAL FIELD

The present invention relates to an apparatus and method of processing a substrate, and more specifically, to an apparatus and method of liquid-treating a substrate with a liquid by supplying the liquid in a bottle to the substrate.

### BACKGROUND ART

In order to manufacture a semiconductor device, various processes, such as cleaning, deposition, photography, etching, and ion implantation, are performed. Among the processes, the photography process includes a coating process of forming a film by applying a photoresist, such as a photoresist, on a surface of the substrate, an exposure process that transfers a circuit pattern to a film formed on the substrate, and a developing process that selectively removes a film formed on the substrate in a region on which the exposure process has been performed or a region opposite to the region.

Typically, a device that performs an application process supplies photoresist from a nozzle onto a rotating substrate to form a liquid film on the substrate. FIG. 1 schematically illustrates a structure of a general liquid supply unit that supplies photoresist to a nozzle. Referring to FIG. 1, a liquid supply unit 9000 stores photoresist in a bottle 9100 in a trap tank 9500, and then supplies the photoresist in the trap tank 9500 to a nozzle 9700.

The bottle 9100 is connected to a gas supply pipe 9310, and the gas supply unit 9300 supplies high pressure gas into the bottle 9100 via the gas supply pipe 9310. Typically, the gas is supplied such that the pressure within the bottle 9100 is raised to tens of kPa in order to cause the photoresist within the bottle 9100 to be delivered to the trap tank 9500 by the gas pressure.

However, the high gas pressure increases the dissolved amount of gas in the photoresist stored in the bottle 9100, and a large amount of bubbles are generated in the photoresist as the photoresist flows along the supply pipes 9910 and 9930 or is applied onto the substrate W. As a result, a smaller amount of photoresist than a set amount is applied to the substrate W, and a defect in air volume occurs while affecting the thickness of the applied liquid film.

### SUMMARY OF THE INVENTION

The present invention has been made in an effort to provide a substrate processing apparatus and a substrate processing method that are capable of improving substrate processing efficiency.

The present invention has also been made in an effort to provide a substrate processing apparatus and a substrate processing method that are capable of preventing a large amount of bubbles from being generated in a liquid supplied to a substrate.

Effects of the present disclosure are not limited to those described above and effects not stated above will be clearly understood to those skilled in the art from the specification and the accompanying drawings.

An exemplary embodiment of the present invention, an apparatus for processing a substrate, the apparatus may further include, a processing unit for processing a substrate; and a liquid supply unit for supplying a liquid to a substrate disposed in the processing unit, wherein the liquid supply unit includes: a bottle in which a storage space for storing a liquid is formed; a supply pipe for providing a path through which the liquid in the bottle flows to the processing unit; a trap tank installed in the supply pipe and having an interior space in which the liquid delivered from the bottle is stored; a pump installed in the supply pipe downstream of the trap tank and providing flow pressure to the fluid flowing in the supply pipe; and a negative pressure forming unit for forming negative pressure in the interior space of the trap tank and delivering the liquid in the storage space of the bottle to the trap tank.

According to the exemplary embodiment of the present invention, the apparatus may further include a gas supply unit for supplying gas to the storage space.

According to the exemplary embodiment of the present invention, the gas supply unit may supplies the gas so that the pressure in the storage space is maintained between normal pressure and pressure 5 kPa higher than the normal pressure.

According to the exemplary embodiment of the present invention, the gas may be inert gas.

According to the exemplary embodiment of the present invention, the negative pressure forming unit includes an ejector to which an inlet pipe, an outlet pipe, and a suction pipe are connected, the suction pipe is connected to the interior space of the trap tank, and the gas introduced through the inlet pipe flows to the outlet pipe through the ejector to may form negative pressure in the interior space.

According to the exemplary embodiment of the present invention, the negative pressure forming unit further may include a cleaning liquid supply member connected to the suction pipe to supply the cleaning liquid to the suction pipe.

According to the exemplary embodiment of the present invention, the apparatus may further include a controller for controlling the negative pressure forming unit, wherein the negative pressure forming unit further includes: a valve for opening and closing the suction pipe; and a first sensor installed in the suction pipe to detect flow of the liquid in the suction pipe, and the controller may controls the negative pressure forming unit to close the valve when the flow of the liquid in the suction pipe is detected by the first sensor.

According to the exemplary embodiment of the present invention, the apparatus may further include a controller for controlling the negative pressure forming unit, wherein the negative pressure forming unit further includes: a valve for opening and closing the suction pipe; and a second sensor installed in the outlet pipe to detect flow of the liquid in the outlet pipe, and the controller may controls the negative pressure forming unit to close the valve when the flow of the liquid in the outlet pipe is detected by the second sensor, and to clean the suction pipe, the ejector, and the outlet pipe by supplying the cleaning liquid to the suction pipe through the cleaning liquid supply member.

According to the exemplary embodiment of the present invention, the negative pressure forming unit may further includes a pressure sensor installed in the suction pipe to measure pressure inside the suction pipe, and the apparatus further comprises: a vessel installed in the supply pipe to suck the liquid in the trap tank and deliver the liquid to the pump; a pressure control unit connected to the vessel to control suction pressure of the vessel; and a controller for controlling the pressure control unit and the negative pressure forming unit.

According to the exemplary embodiment of the present invention, the controller may controls the negative pressure forming unit and the pressure control unit so that a movement speed of a photoresist transferred from the bottle to the trap tank is constant.

According to the exemplary embodiment of the present invention, the negative pressure forming unit further includes a valve that opens and closes the suction pipe, and the controller may controls the pressure control unit so that suction pressure of the vessel when the valve is closed is greater than suction pressure of the vessel when the valve is open.

According to the exemplary embodiment of the present invention, the liquid is a photoresist, and the cleaning liquid may be a thinner.

An exemplary embodiment of the present invention, a method of processing a substrate, the method comprising: delivering a liquid stored in a bottle to a trap tank by forming negative pressure in an interior space of the trap tank, and supplying the liquid delivered to the trap tank to a substrate to process the substrate, wherein gas may be supplied to the bottle while the liquid stored in the bottle is delivered to the trap tank.

According to the exemplary embodiment of the present invention, the gas may be supplied so that pressure in a storage space of the bottle is equal to or greater than normal pressure and is equal to or less than pressure 5 kPa higher than the normal pressure.

According to the exemplary embodiment of the present invention, when the liquid flows into a negative pressure forming unit that forms the negative pressure, a pipe forming negative pressure to the trap tank may be closed in the negative pressure forming unit.

According to the exemplary embodiment of the present invention, the negative pressure is formed by an ejector, and when the liquid flows into the ejector, the ejector may be cleaned.

According to the exemplary embodiment of the present invention, the liquid is a photoresist, and the cleaning liquid for cleaning the ejector may be a thinner.

An exemplary embodiment of the present invention, an apparatus for processing a substrate, the apparatus comprising: a processing unit for processing a substrate; a liquid supply unit for supplying a photoresist liquid to a substrate disposed in the processing unit; and a controller for controlling the liquid supply unit, wherein the liquid supply unit includes: a bottle formed with a storage space for storing the photoresist liquid; a supply pipe for providing a path through which the photoresist liquid in the bottle flows to the processing unit; a trap tank installed in the supply pipe and having an interior space in which the photoresist liquid delivered from the bottle is stored; a pump installed in the supply pipe downstream of the trap tank and providing a flow pressure to the photoresist liquid flowing in the supply pipe; a negative pressure forming unit for forming negative pressure in the interior space of the trap tank and delivering the photoresist liquid from the storage space of the bottle to the interior space of the trap tank; and a gas supply unit for supplying inert gas to the storage space of the bottle to maintain pressure of the storage space between normal pressure and pressure 5 kPa higher than normal pressure, and the negative pressure forming unit may include, a suction pipe connected to the interior space of the trap tank; an ejector connected to the suction pipe; an inlet pipe that is connected to the ejector and introduces gas; an outlet pipe through which the gas passing through the ejector flows out; and a valve for opening and closing the suction pipe.

According to the exemplary embodiment of the present invention, the negative pressure forming unit further includes: a valve for opening and closing the suction pipe; a cleaning liquid supply member connected to the suction pipe; and a sensor installed in the outlet pipe to detect flow of a photoresist liquid in the outlet pipe, and when the sensor detects the flow of the photoresist liquid in the outlet pipe, the controller controls the negative pressure forming unit to close the valve and to clean the suction pipe, the ejector, and the outlet pipe by supplying the cleaning liquid to the suction pipe through the cleaning liquid supply member.

According to the exemplary embodiment of the present invention, the apparatus may further include a vessel installed in the supply pipe to suck the photoresist liquid in the trap tank and deliver the photoresist liquid to the pump; and a pressure control unit connected to the vessel to control suction pressure of the vessel, wherein the controller may controls the negative pressure forming unit and the pressure control unit so that a movement speed of the photoresist liquid transferred from the bottle to the trap tank is constant.

According to the exemplary embodiment of the present invention, it is possible to improve substrate processing efficiency.

According to the exemplary embodiment of the present invention, the vessel unit may form suction pressure to transfer the liquid stored in the trap tank to the pump.

According to the exemplary embodiment of the present invention, it is possible to prevent a large amount of bubbles from being generated in the liquid supplied to the substrate.

According to the exemplary embodiment of the present invention, it is possible to deliver the liquid in the bottle to the trap tank at a constant speed.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram schematically illustrating a structure of a general liquid supply unit that supplies a photoresist liquid to a nozzle.

FIG. 2 is a diagram schematically illustrating a substrate processing apparatus according to an exemplary embodiment of the present invention.

FIG. 3 is a diagram schematically illustrating one example of a liquid treating chamber of FIG. 2.

FIG. 4 is a diagram schematically illustrating an example of a negative pressure forming unit of FIG. 2.

FIG. 5 is a diagram schematically illustrating an example of a vessel unit of FIG. 2.

FIG. 6 is a diagram schematically illustrating an exemplary embodiment of the substrate processing apparatus of FIG. 2 after replacing a bottle.

FIGS. 7 to 8 are diagrams illustrating a process of closing a valve installed in a suction pipe.

FIGS. 9 to 10 are diagrams illustrating a process of cleaning an ejector.

FIG. 11 is a diagram schematically illustrating another exemplary embodiment of the substrate processing apparatus of FIG. 2.

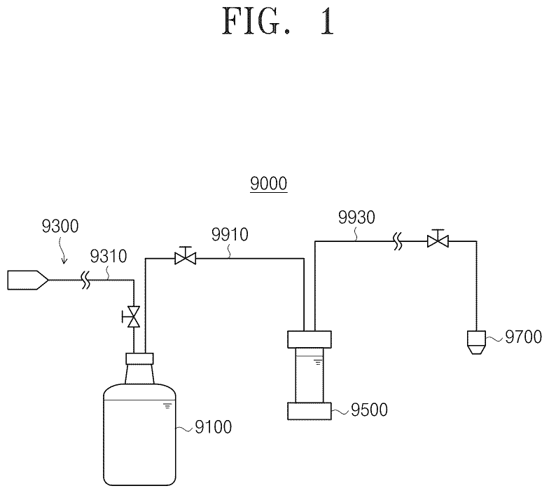

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

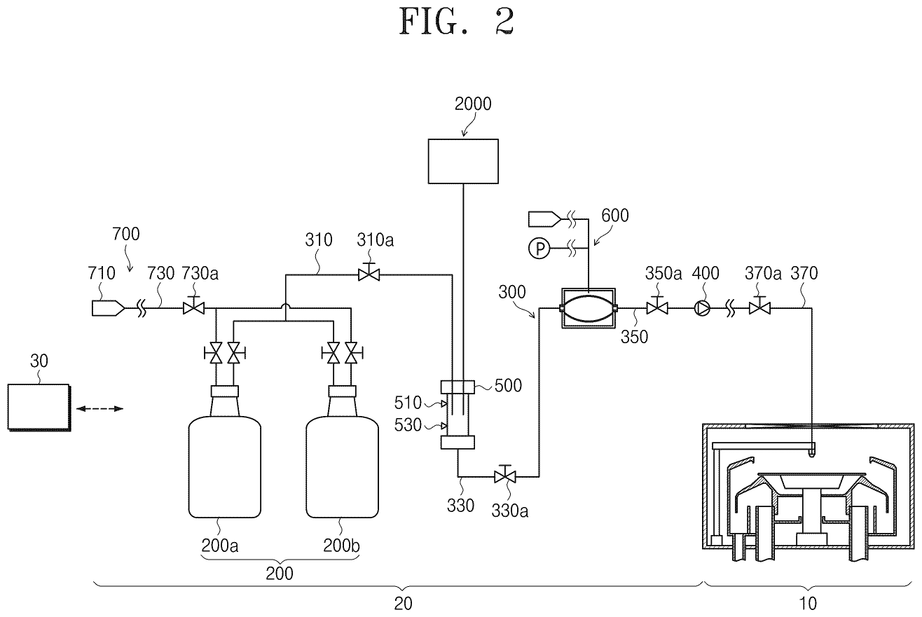

Hereinafter, an exemplary embodiment of the present invention will be described with reference to FIGS. 2 to 10.

In the following exemplary embodiment, the case where a substrate processing apparatus is an apparatus for performing a coating process of applying a photoresist on a substrate will be described as an example. However, unlike this, the substrate processing apparatus may be an apparatus for applying an antireflection film, a protective film, or another kind of liquid onto a substrate.

FIG. 2 is a diagram schematically illustrating a substrate processing apparatus according to an exemplary embodiment of the present invention. Referring to FIG. 2, a substrate processing apparatus 1 includes a liquid treating chamber 10, a liquid supply unit 20, and a controller 30. The liquid treating chamber 10 applies a photoresist film to a substrate W loaded therein. The liquid supply unit 20 supplies a photoresist to the liquid treating chamber 10. The controller 30 controls the liquid treating chamber 10 and the liquid supply unit 20.

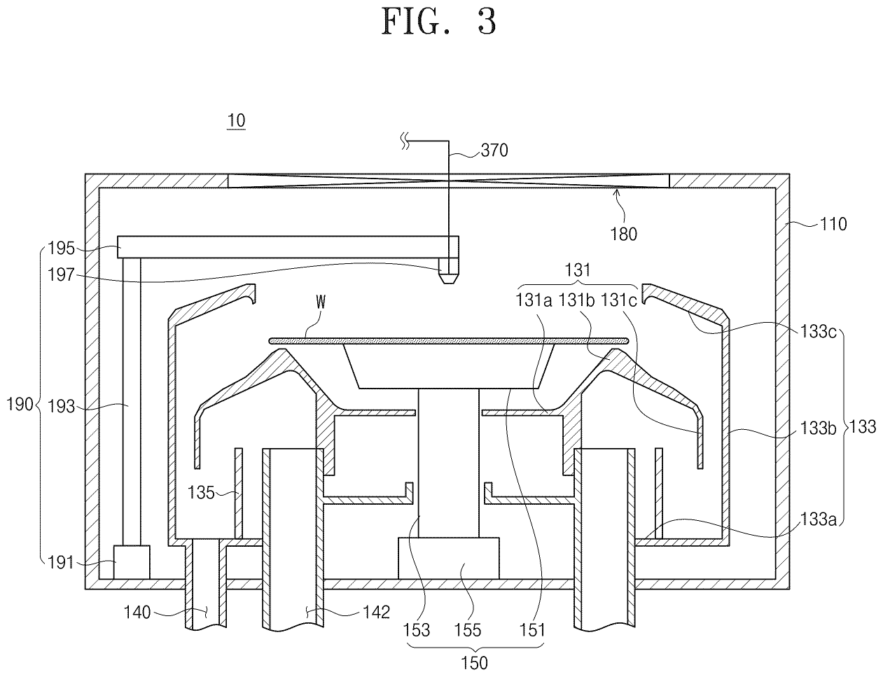

FIG. 3 is a diagram schematically illustrating an example of the liquid treating chamber of FIG. 2. Referring to FIG. 2, the liquid treating chamber 10 may include a housing 110, a cup 133, a support unit 150, a guide ring 131, an airflow supply unit 180, and a nozzle unit 190.

The housing 110 provides space therein. The housing 110 is provided in a generally rectangular parallelepiped shape. An opening (not illustrated) is formed at one side of the housing 110. The opening (not illustrated) functions as an entrance through which the substrate W is loaded into the interior space or the substrate W is unloaded from the interior space. Also, a door (not illustrated) is installed in an area adjacent to the entrance to selectively open and close the entrance. A door (not illustrated) blocks the entrance and seals the interior space from the outside while the processing process is performed on the substrate W loaded into the interior space. The cup 133, the support unit 150, the guide ring 131, and the nozzle unit 190 may be disposed in the interior space of the housing 110.

The cup 133 may be provided to surround the support unit 150 and the guide ring 131. The cup 133 may include a bottom wall 133a, a side wall 133b, and an upper wall 133c.

The bottom wall 133a may have a circular plate shape having a hollow. A discharge pipe 140 is connected to the bottom wall 133a. After processing the substrate W, the liquid scattered from the substrate W is discharged to the outside of the cup 133 through the discharge pipe 140.

An exhaust pipe 142 is connected to the bottom wall 133a. The exhaust pipe 142 is connected to the bottom wall 133a from the inner side than the exhaust pipe 140. Fume and airflow flowing in the cup 133 are exhausted to the outside of the cup 133 through the exhaust pipe.

The gas-liquid separation plate 135 may be installed on the bottom wall 133a. The gas-liquid separation plate 135 may be provided in an annular shape. The gas-liquid separation plate 135 is installed between the discharge pipe 140 and the exhaust pipe 142. The gas-liquid separation plate 135 prevents liquids used for processing the substrate W from flowing into the exhaust pipe 142.

The sidewall 133b may be provided in an annular ring shape surrounding the guide ring 131. The sidewall 133b may extend in a vertical direction from a side end of the bottom wall 133a.

The upper wall 133c may extend in a direction from an upper end of the side wall 133b toward a central axis of the outer cup 133. An inner surface of the upper wall 133c may extend to be inclined upward with respect to the ground as it approaches a central axis of the outer cup 133. The upper wall 133c may be provided to have a ring shape when viewed from above. While the processing of the substrate W is performed, the upper end of the upper wall 133c may be positioned to be higher than the upper surface of the substrate W supported by the support unit 150.

The support unit 150 supports and rotates the substrate W in a processing space. The support unit 150 may be a spin chuck that supports and rotates the substrate W. The support unit 150 may include a body 151, a support shaft 153, and a driving unit 155.

The guide ring 131 may have an inner wall 131a, an upper wall 131b, and an outer wall 131c. The inner wall 131a, the upper wall 131b, and the outer wall 131c may be combined with each other to provide a space in which the lower portion is open. The support shaft 153 of the support unit 150 may be surrounded by the inner wall 131a. The outer wall 131c may be combined with the cup 133 to form a discharge path through which the processing medium is discharged. The upper wall 131b may be provided to be inclined upward toward the outside from the inner wall 131a, and may then have a shape inclined downward toward the outer wall 131c.

The body 151 may have a top surface on which the substrate W is seated. The top surface of the body 151 may be provided in an approximately circular shape when viewed from the top. The top surface of the body 151 may have a diameter smaller than that of the substrate W. An adsorption hole (not illustrated) may be formed in the body 151. The adsorption hole (not illustrated) may vacuum-adsorb the substrate W seated on the top surface of the body 151.

The support shaft 153 is coupled with the body 151. The support shaft 153 may be coupled to a lower surface of the body 151. The longitudinal direction of the support shaft 153 may be provided in a vertical direction. The driving unit 155 may provide power for rotating the support shaft 153 with respect to a central axis thereof and for moving the support shaft 153 in a vertical direction. Accordingly, a relative height between the support unit 150 and the cup 133 may be adjusted.

An airflow supply unit 180 is installed on an upper end of the housing 110. The airflow supply unit 180 may supply airflow having a temperature and/or humidity adjusted to the interior space. The airflow supply unit 180 may be a Fan Filter Unit (FFU).

The nozzle unit 190 is provided in the housing 110. The nozzle unit 190 receives a liquid from the liquid supply unit 20 and supplies the liquid to the substrate W supported by the support unit 150. The nozzle unit 190 may include a driver 191, a support rod 193, an arm 195, and a nozzle 197.

The support rod 193 is located in the interior space of the housing 110. The support rod 193 is located on one side of a processing container 420 in the interior space. The support rod 193 may have a rod shape whose longitudinal direction faces a vertical direction.

The arm 195 is coupled to an upper end of the support rod 193. The arm 195 extends vertically from the longitudinal direction of the support rod 193. The nozzle 197 to be described later may be fixedly coupled to the end of the arm 195.

The driver 191 is coupled with the support rod 193. The driver 191 may be disposed on the bottom surface of the housing 110. The driver 191 provides driving force for rotating the support rod 193. The driver 191 may be provided as a motor.

The liquid supply unit 20 supplies a photoresist to the nozzle 197 provided in the liquid treating chamber 10.

Referring to FIG. 2, the liquid supply unit 20 includes a bottle 200, a supply pipe 300, a pump 400, a trap tank 500, a negative pressure forming unit 2000, a vessel unit 600, and a gas supply unit 700.

The bottle 200 has a storage space for storing photoresists. A plurality of bottles 200 may be provided. For example, the bottle 200 may include a first bottle 200a and a second bottle 200b. Accordingly, first, a photoresist is supplied from the first bottle 200a to the trap tank 500. When the photoresist is exhausted from the first bottle 200a, the photoresist is supplied from the second bottle 200b to the trap tank 500. While the photoresist is supplied from the second bottle 200b, the first bottle 200a from which the photoresist is exhausted is replaced with a new bottle 200 filled with the photoresist. The first bottle 200a and the second bottle 200b have the same or similar structures.

The supply pipe 300 supplies the photoresist in the bottle 200 to the liquid treating chamber 10. The supply pipe 300 is provided with a flow path through which the photoresist may flow. The trap tank 500, the vessel unit 600, and the pump 400 are installed in the supply pipe 300. The trap tank 500, the vessel unit 600, and the pump 400 are sequentially disposed in a direction from the upstream to the downstream. The supply pipe 300 includes a first pipe 310, a second pipe 330, a third pipe 350, and a fourth pipe 370. The first pipe 310 connects the bottle 200 and the trap tank 500. The second pipe 330 connects the trap tank 500 and the vessel unit 600. The third pipe 350 connects the vessel unit 600 and the pump 400. The fourth pipe 370 connects the pump 400 and the nozzle 197.

Opening and closing valves 310a, 330a, 350a, and 370a for opening and closing the flow paths are installed in the first to fourth pipes 310, 330, 350, and 370a, respectively.

The photoresist stored in the bottle 200 is supplied to the trap tank 500. The trap tank 500 has an interior space for temporarily storing photoresists. Water level detection sensors 510 and 530 are installed in the trap tank 500. The water level detection sensors 510 and 530 detect the water level of the photoresist stored in the interior space of the trap tank 500. A plurality of water level detection sensors 510 and 530 may be provided. When the water level is detected by the water level detection sensors 510 and 530, the controller 30 may transmit information on the amount of photoresist remaining in the trap tank 500 to the user.

The pump 400 provides a flow pressure for flowing the photoresist delivered from the vessel 610 to be described later to the liquid treating chamber 10. The pump 400 is installed in the supply pipe 300 downstream from the vessel 610.

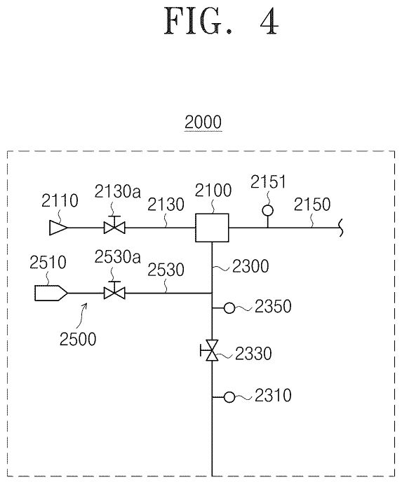

The negative pressure forming unit 2000 is connected to the trap tank 500 to form negative pressure in the interior space of the trap tank 500. FIG. 4 is a diagram schematically illustrating an example of the negative pressure forming unit 2000 of FIG. 2.

Referring to FIG. 4, the negative pressure forming unit 2000 includes an ejector 2100, a gas supply source 2110, an outlet pipe 2150, an inlet pipe 2130, a suction pipe 2300, a cleaning liquid supply member 2500, a first sensor 2310, a second sensor 2151, and a pressure sensor 2350.

The inlet pipe 2130 and the outlet pipe 2150 are connected to both ends of the ejector 2100, respectively, and the suction pipe 2300 is connected to a lower end of the ejector 2100. The gas supplied from the gas supply source 2110 may flow into the ejector 2100 through the inlet pipe 2130, and may be discharged to the outside through the outlet pipe 2150.

Due to the change in the inner passage area of the ejector 2100, the speed of the gas passing through the ejector 2100 becomes faster than the speed before passing, and negative pressure is formed in the ejector 2100. Accordingly, as the gas inside the trap tank 500 flows through the ejector 2100 to the outlet pipe 2150, negative pressure is formed in the interior space of the trap tank 500.

A valve 2330 is installed at the suction pipe 2300. The valve 2330 may be an on/off valve.

The cleaning liquid supply member 2500 cleans the ejector 2100. As the cleaning liquid, a liquid for removing the photoresist remaining in the ejector 2100 is used. According to an example, the cleaning liquid may be a thinner. The cleaning liquid supply member 2500 includes a cleaning liquid supply source 2510 and a cleaning liquid supply pipe 2530. The cleaning liquid supply pipe 2530 is provided with a valve 2530a. The valve 2530a may be an on/off valve. The cleaning liquid supply pipe 2530 is connected to the suction pipe 2300 and may supply the cleaning liquid to the suction pipe 2300. The cleaning liquid supply pipe 2530 may be connected to the suction pipe 2300 at a downstream side than the valve 2330 installed in the suction pipe.

The first sensor 2310 is installed in the suction pipe 2300. The first sensor 2310 detects whether a photoresist is introduced into the suction pipe 2300. The first sensor 2310 may be an optical sensor. The first sensor 2310 may be installed in the suction pipe 2300 upstream from the valve 2330.

The second sensor 2151 is installed in the outlet pipe 2150. The second sensor 2151 detects whether a photoresist is introduced into the ejector 2100. The second sensor 2151 may be an optical sensor.

The pressure sensor 2350 is installed on the suction pipe 2300. The pressure sensor 2350 measures the pressure inside the suction pipe 2300. The pressure sensor 2350 may be located downstream from the valve 2330 in the suction pipe 2300.

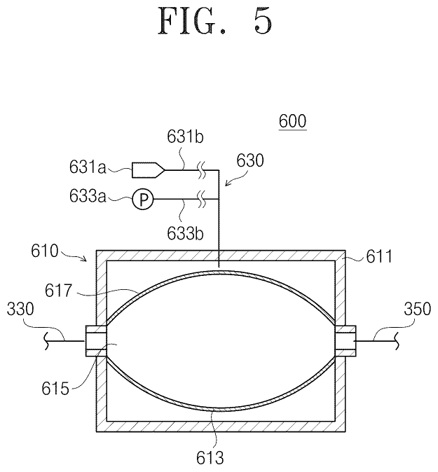

FIG. 5 is a diagram schematically illustrating an example of the vessel unit of FIG. 2. Referring to FIG. 5, the vessel unit 600 includes a vessel 610 and a pressure control unit 630.

The vessel 610 has a case 611 and a tube 613. The case 611 may be provided in a cylindrical shape having an inner space. The tube 613 is located in the interior space of the case 611. The tube 613 is made of an elastic material that is contractible and expandable. The interior space of the tube 613 is provided with a flow path 615 through which a photoresist may flow. A space between the case 611 and the tube 613 is provided as an adjustment space 617 for adjusting the volume of the flow path 615.

The pressure control unit 630 includes a gas supply source 631a and a suction pump 633a. The gas supply source 631a may supply gas to the adjustment space 617 through the gas supply pipe 631b, and the suction pump 633a may adjust pressure of the flow path 615 by sucking gas from the adjustment space 617 through the suction pipe 633b. For example, when the gas supply source 631a supplies gas, the tube 613 is contracted to reduce the volume of the flow path 615 and increase the internal pressure. When the suction pump 633a sucks gas of the adjustment space 617, the tube 613 is expanded to increase the volume of the flow path 615 and decrease the internal pressure.

When the vessel unit 600 sucks the photoresist inside the trap tank 500, in a state where the valve 330a installed in the second pipe 330 is opened and the valve 350a installed in the third pipe 350 is closed, gas in the adjustment space 617 is sucked from the suction pump 633a, and the photoresist flows from the trap tank 500 to the vessel unit 600.

When the vessel unit 600 delivers the photoresist to the pump 400, in a state where the valve 330a installed in the second pipe 330 is closed and the valve 350a installed in the third pipe 350 is opened, gas is supplied from the gas supply source 631a to the adjustment space 617, and the photoresist flows from the vessel unit 600 to the pump 400.

Referring back to FIG. 2, the gas supply unit 700 supplies gas to the storage space of the bottle 200. The gas supply unit 700 may include a gas supply source 710, a gas supply pipe 730, and a valve 730a.

Gas is stored in the gas supply source 710. The gas may be inert gas. According to the example, the gas may be nitrogen gas (N2). The gas supply pipe 730 may be connected to the gas supply source 710 and the bottle 200 to supply gas to the storage space of the bottle 200. The valve 730a may be installed in the gas supply pipe 730 to open and close an internal passage thereof. The gas supply unit 700 fills the empty space inside the bottle 200 with gas when the stored photoresist of the bottle 200 is delivered to the trap tank 500. Accordingly, external air may be prevented from flowing into the bottle 200 and contaminating the photoresist. In addition, deformation of the bottle 200 may be prevented by maintaining the internal pressure of the bottle 200 at a certain pressure or greater while the liquid is supplied from the bottle 200 to the trap tank 500.

Since negative pressure is formed in the interior space of the trap tank 500 by the negative pressure forming unit 2000, and the gas supply unit 700 micro-pressurizes the photoresist stored in the bottle 200, the photoresist may be stably delivered from the bottle 200 to the trap tank 500. According to the example, the gas supply unit 700 may supply gas so that the pressure of the gas in the bottle 200 is higher than normal pressure and at the same time is lower than pressure 5 kPa higher than normal pressure.

Since the amount of gas supplied into the bottle 200 is small, a large amount of gas is prevented from being dissolved in the photoresist delivered from the bottle 200. Accordingly, it is possible to prevent a large amount of air bubbles from being generated in the photoresist when the photoresist moves through the supply pipe 300.

The controller 30 controls the substrate processing apparatus 1 to perform a substrate processing method described below.

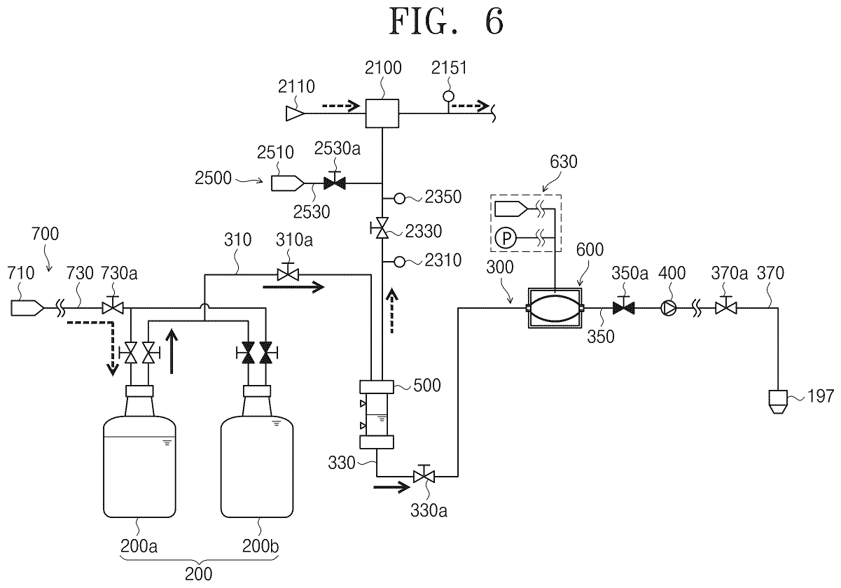

FIGS. 6 to 10 are diagrams schematically illustrating an exemplary embodiment of a process of supplying a liquid in the substrate processing apparatus of FIG. 2. In FIGS. 6 to 10, the valve filled with the inside is in a closed state for preventing a fluid from flowing, and the valve with the empty inside is in an open state for allowing a fluid to flow. A solid line arrow indicates a flow direction of the photoresist, and a dotted arrow indicates a flow direction of gas. Furthermore, the first and second sensors 2310 and 2151 filled with the inside indicate a state in which a flow of the photoresist is detected, and the first and second sensors 2310 and 2151 emptied of the inside indicate a state in which a flow of the photoresist is not detected.

Referring to FIG. 6, the gas supply unit 700 supplies gas to the bottle 200 to provide gas pressure to the bottle 200, and the negative pressure forming unit 2000 supplies gas to the ejector 2100 to form negative pressure in the inner space of the trap tank 500. Also, in the suction unit, the pressure control unit 630 sucks gas in the second flow path 617 to form suction pressure in the first flow path 615. Accordingly, the photoresist stored in the bottle 200 is delivered to the trap tank 500 to fill the interior space of the trap tank 500, and the photoresist in the trap tank 500 is delivered to the vessel 610.

The controller 30 may control the negative pressure forming unit 2000 and the pressure control unit 630 so that the difference between the pressure measured through the pressure sensor 2350 and the pressure provided by the pressure control unit 630 is constant. Accordingly, the movement speed of the photoresist delivered from the bottle 200 to the trap tank 500 may be constantly controlled.

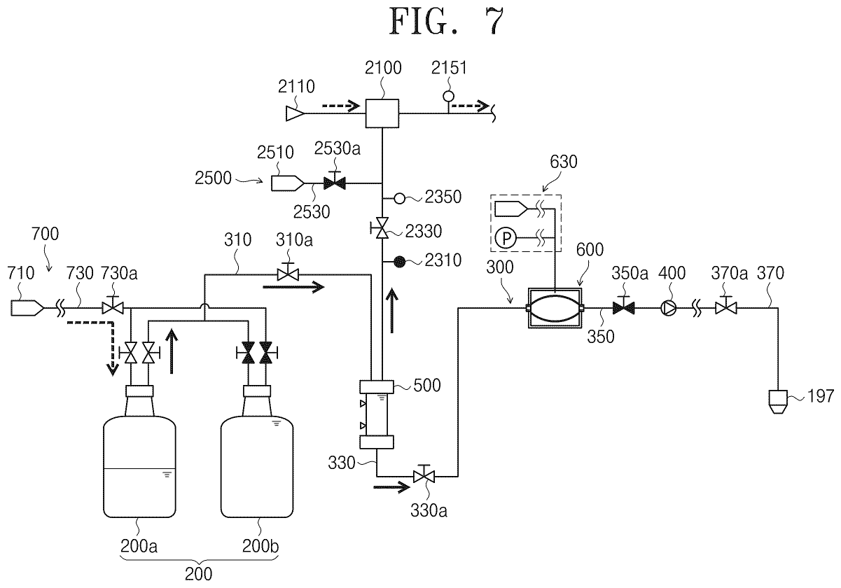

When the photoresist supplied from the bottle 200 is filled in the interior space of the trap tank 500 at a predetermined level or more, a part of the photoresist delivered into the trap tank 500 flows into the suction pipe 2300 as illustrated in FIG. 7. The photoresist introduced into the suction pipe 2300 is detected by the first sensor 2310, and the detection result is transmitted to the controller 30. The controller 30 receives a detection signal from the first sensor 2310 and closes a valve installed in the suction pipe 2300.

Since the valve 2330 installed in the suction pipe 2300 is closed so that negative pressure is not formed in the interior space of the trap tank 500, the photoresist in the trap tank 500 is delivered to the vessel 610 by the suction pressure of the vessel 610, and the photoresist is delivered from the bottle 200 to the trap tank 500 by the amount delivered from the trap tank 500 to the vessel 610.

The controller 30 may control the pressure control unit 630 so that the suction pressure of the vessel 610 is smaller than when the valve 2330 in the suction pipe 2300 is opened. Accordingly, the movement speed of the photoresist delivered from the bottle 200 to the trap tank 500 may be kept constant before and after the valve 2330 installed in the suction pipe 2300 is closed.

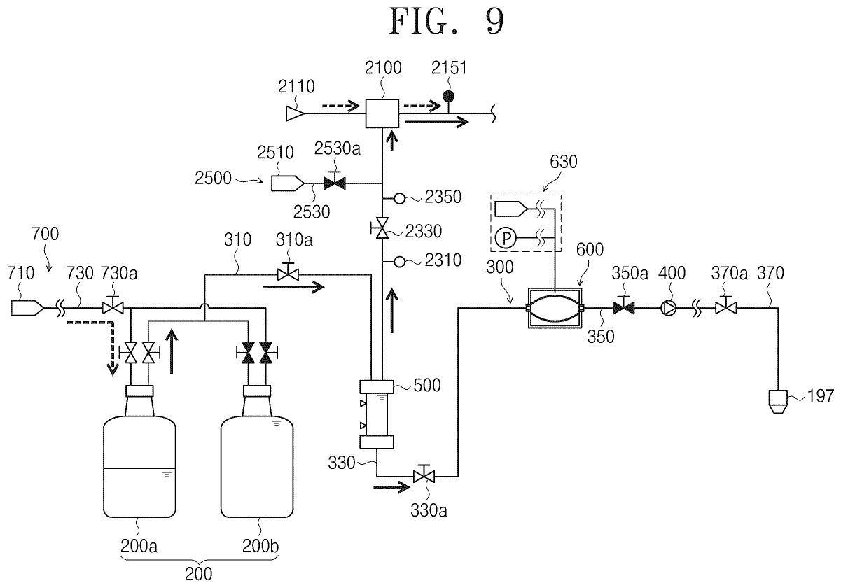

When the first sensor 2310 does not detect the flow of the photoresist inside the suction pipe 2300 due to a failure or malfunction, the photoresist is introduced into the ejector 2100 and then flows into the outlet pipe 2150 as illustrated in FIG. 9. Some of the photoresists introduced into the ejector 2100 may remain or be deposited in the ejector 2100. In this case, the second sensor 2151 detects the photoresist flowing inside the outlet pipe 2150.

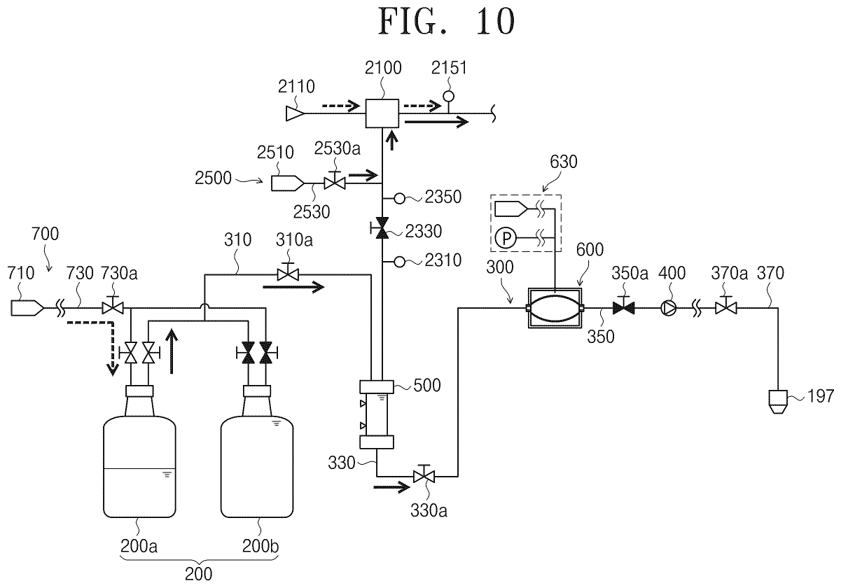

The controller 30 receives a signal from the second sensor 2151 that the photoresist in the outlet pipe 2150 flows, closes the valve in the suction pipe 2300, and supplies the cleaning liquid to the suction pipe 2300 through the cleaning liquid supply member 2500 as illustrated in FIG. 10. The cleaning liquid flows in the order of the suction pipe 2300, the ejector 2100, and the outlet pipe 2150 by the negative pressure of the ejector 2100. The cleaning liquid removes the photoresist in the suction pipe 2300, the ejector 2100, and the outlet pipe 2150 to prevent solidification of the photoresist.

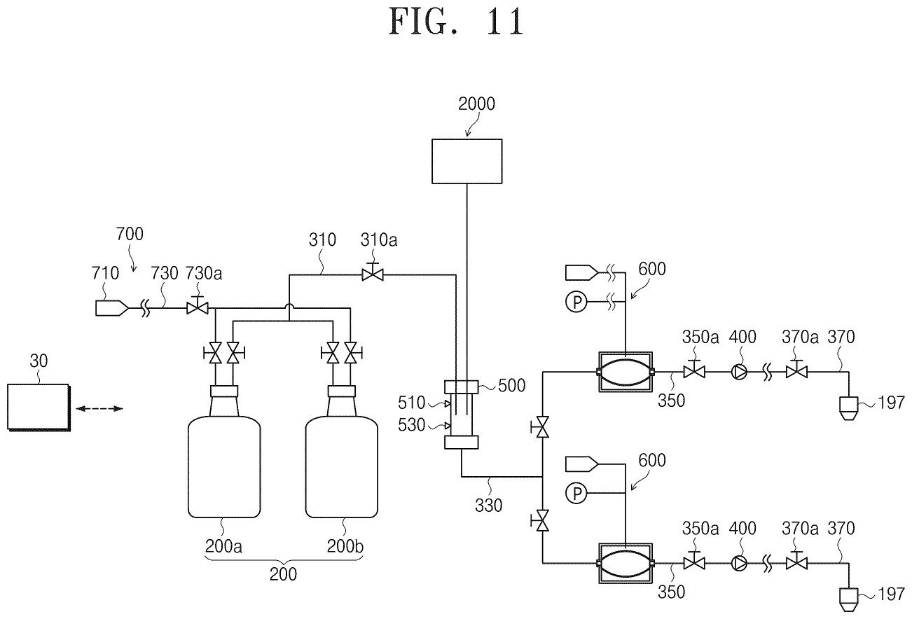

In the above-described exemplary embodiment of FIG. 2, a case in which one nozzle 197 is connected to the supply pipe 300 to receive a liquid from the trap tank 500 has been described as an example. However, the present invention is not limited thereto, and the supply pipe 300 connected to the trap tank 500 may be branched to be connected to a plurality of nozzles 197 as illustrated in FIG. 11.

In the above-described exemplary embodiment of FIG. 2, a case in which a plurality of bottles 200 is provided has been described as an example. However, the present invention is not limited thereto, and one bottle 200 may be provided to store liquid.

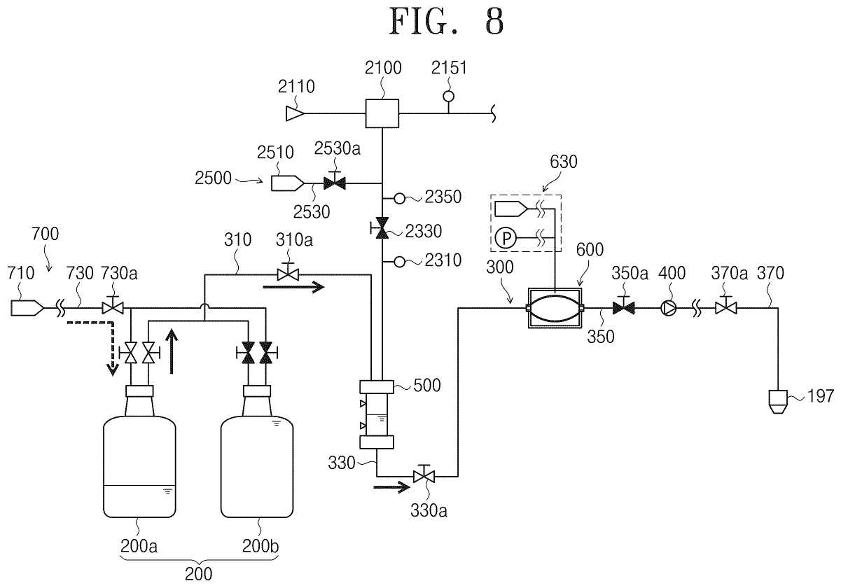

In the above-described exemplary embodiment of FIG. 8, a case where in order to make the movement speed of the photoresist delivered from the bottle 200 to the trap tank 500 constant, the negative pressure forming unit 2000 and the pressure control unit 630 are controlled has been described. However, the present invention is not limited thereto, and the pressure of one of the negative pressure forming unit 2000 and the pressure control unit 630 may be maintained at a fixed pressure and the pressure of the other unit may be controlled.

In the above-described exemplary embodiment of FIG. 9, a case where when a photoresist is detected by the first sensor 2310, the valve 2330 installed in the suction pipe 2300 is closed has been described. However, the present invention is not limited thereto, and when a photoresist is detected by the water level sensor 510 provided at the upper end side of the trap tank 500, a valve installed in the suction pipe 2300 may be controlled to be closed.

In the above-described exemplary embodiments, a case where when a photoresist is detected by the second sensor 2151, the valve is closed, and the cleaning liquid supply member 2500 supplies the cleaning liquid to the suction pipe 2300 has been described. However, the present invention is not limited thereto, and the second sensor 2151 and the cleaning liquid supply member 2500 may not be provided to the negative pressure forming unit 2000.

In the above-described exemplary embodiments, a case in which the photoresist temporarily stored in the trap tank 500 is sucked through the vessel unit 600 and delivered to the pump 400 has been described. Alternatively, the vessel unit 600 is not provided to the liquid supply unit, and the photoresist inside the trap tank 500 may flow to the pump 400 by the suction pressure of the pump 400.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

1. An apparatus for processing a substrate, the apparatus comprising:
a processing unit for processing a substrate; and
a liquid supply unit for supplying a liquid to a substrate disposed in the processing unit,
wherein the liquid supply unit includes:
a bottle in which a storage space for storing a liquid is formed;
a supply pipe for providing a path through which the liquid in the bottle flows to the processing unit;
a trap tank installed in the supply pipe and having an interior space in which the liquid delivered from the bottle is stored;
a pump installed in the supply pipe downstream of the trap tank and providing flow pressure to the fluid flowing in the supply pipe; and
a negative pressure forming unit for forming negative pressure in the interior space of the trap tank and delivering the liquid in the storage space of the bottle to the trap tank.

2. The apparatus of claim 1, further comprising:
a gas supply unit for supplying gas to the storage space.

3. The apparatus of claim 2, wherein the gas supply unit supplies the gas so that the pressure in the storage space is maintained between normal pressure and pressure 5 kPa higher than the normal pressure.

4. The apparatus of claim 2, wherein the gas is inert gas.

5. The apparatus of claim 1, wherein the negative pressure forming unit includes an ejector to which an inlet pipe, an outlet pipe, and a suction pipe are connected,
the suction pipe is connected to the interior space of the trap tank, and
the gas introduced through the inlet pipe flows to the outlet pipe through the ejector to form negative pressure in the interior space.

6. The apparatus of claim 5, wherein the negative pressure forming unit further includes a cleaning liquid supply member connected to the suction pipe to supply the cleaning liquid to the suction pipe.

7. The apparatus of claim 6, further comprising:
a controller for controlling the negative pressure forming unit,
wherein the negative pressure forming unit further includes:
a valve for opening and closing the suction pipe; and
a first sensor installed in the suction pipe to detect flow of the liquid in the suction pipe, and
the controller controls the negative pressure forming unit to close the valve when the flow of the liquid in the suction pipe is detected by the first sensor.

8. The apparatus of claim 6, further comprising:
a controller for controlling the negative pressure forming unit,
wherein the negative pressure forming unit further includes:
a valve for opening and closing the suction pipe; and
a second sensor installed in the outlet pipe to detect flow of the liquid in the outlet pipe, and
the controller controls the negative pressure forming unit to close the valve when the flow of the liquid in the outlet pipe is detected by the second sensor, and to clean the suction pipe, the ejector, and the outlet pipe by supplying the cleaning liquid to the suction pipe through the cleaning liquid supply member.

9. The apparatus of claim 5, wherein the negative pressure forming unit further includes a pressure sensor installed in the suction pipe to measure pressure inside the suction pipe, and
the apparatus further comprises:
a vessel installed in the supply pipe to suck the liquid in the trap tank and deliver the liquid to the pump;
a pressure control unit connected to the vessel to control suction pressure of the vessel; and
a controller for controlling the pressure control unit and the negative pressure forming unit.

10. The apparatus of claim 9, wherein the controller controls the negative pressure forming unit and the pressure control unit so that a movement speed of a photoresist transferred from the bottle to the trap tank is constant.

11. The apparatus of claim 9, wherein the negative pressure forming unit further includes a valve that opens and closes the suction pipe, and
the controller controls the pressure control unit so that suction pressure of the vessel when the valve is closed is greater than suction pressure of the vessel when the valve is open.

12. The apparatus of claim 6, wherein the liquid is a photoresist, and
the cleaning liquid is a thinner.

13. (canceled)

14. (canceled)

15. (canceled)

16. (canceled)

17. (canceled)

18. An apparatus for processing a substrate, the apparatus comprising:
a processing unit for processing a substrate;
a liquid supply unit for supplying a photoresist liquid to a substrate disposed in the processing unit; and
a controller for controlling the liquid supply unit,
wherein the liquid supply unit includes:
a bottle formed with a storage space for storing the photoresist liquid;
a supply pipe for providing a path through which the photoresist liquid in the bottle flows to the processing unit;
a trap tank installed in the supply pipe and having an interior space in which the photoresist liquid delivered from the bottle is stored;
a pump installed in the supply pipe downstream of the trap tank and providing a flow pressure to the photoresist liquid flowing in the supply pipe;
a negative pressure forming unit for forming negative pressure in the interior space of the trap tank and delivering the photoresist liquid from the storage space of the bottle to the interior space of the trap tank; and
a gas supply unit for supplying inert gas to the storage space of the bottle to maintain pressure of the storage space between normal pressure and pressure 5 kPa higher than normal pressure, and
the negative pressure forming unit includes:
a suction pipe connected to the interior space of the trap tank;
an ejector connected to the suction pipe;
an inlet pipe that is connected to the ejector and introduces gas;
an outlet pipe through which the gas passing through the ejector flows out; and
a valve for opening and closing the suction pipe.

19. The apparatus of claim 18, wherein the negative pressure forming unit further includes:
a valve for opening and closing the suction pipe;
a cleaning liquid supply member connected to the suction pipe; and
a sensor installed in the outlet pipe to detect flow of a photoresist liquid in the outlet pipe, and
when the sensor detects the flow of the photoresist liquid in the outlet pipe, the controller controls the negative pressure forming unit to close the valve and to clean the suction pipe, the ejector, and the outlet pipe by supplying the cleaning liquid to the suction pipe through the cleaning liquid supply member.

20. The apparatus of claim 18, further comprising:
a vessel installed in the supply pipe to suck the photoresist liquid in the trap tank and deliver the photoresist liquid to the pump; and
a pressure control unit connected to the vessel to control suction pressure of the vessel,
wherein the controller controls the negative pressure forming unit and the pressure control unit so that a movement speed of the photoresist liquid transferred from the bottle to the trap tank is constant.
